(19) United States
(12) Patent Application Publication
(10) Pub. No.: US 2006/0273331 A1
(43) Pub. Date: Dec. 7, 2006

(54) Two-terminal LED device with tunable color

(76) Inventors: Kevin Len Li Lim, Perak (MY); Yue Hoong Lau, Penang (MY); Joon Chok Lee, Sarawak (MY); Janet Bee Yin Chua, Perak (MY)

Correspondence Address: AVAGO TECHNOLOGIES, LTD., P.O. BOX 1920, DENVER, CO, 80201-1920, US

(21) Appl. No.: 11/147,056

(22) Filed: Jun. 7, 2005

(51) Int. Cl. H01L 33/00

(52) U.S. Cl. 257/80

(57) ABSTRACT

A two-terminal light-emitting diode (“LED”) device has a first terminal and a second terminal, and a first color LED and a second color LED. An intensity control device is coupled to the first color LED and a control circuit controls the intensity control device so as to produce a selected light intensity from the first color LED according to a control signal provided to the first terminal. The control signal also provides electrical power to the first color LED and to the second color LED.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### BACKGROUND OF THE INVENTION

The invention relates to light-emitting diode (“LED”) devices, and more particularly to a two-terminal LED device producing selectable color according to a supply signal.

An LED is a semiconductor device capable of emitting light when an electric current flows through it. LEDs are used in many applications, such as electronic displays, traffic signals, and video signs. LEDs emit monochromatic light, i.e., the wavelength of light emitted by an LED falls within a narrow range, typically about 20-50 nanometers (“nm”). Different types of LEDs emit different wavelengths (colors) of light. Individual LEDs emitting different colors are often used in an LED module or LED device, such as combining a red-emitting LED (“red LED”), a green-emitting (“green LED”) and a blue-emitting LED (“blue LED”) in an LED device that emits white light. The total combined emission from the LED device is a combination of the various colors emitted by the LEDs.

Such LED devices are commonly called “RGB LED modules.” A particular type of RGB LED module is a “white LED module,” which combines RGB light to emit white light.

Many conventional 2-terminal RGB LED modules emit a fixed light output. In other words, one cannot tune the color output of the module. Unfortunately, LEDs age and perform differently at different temperatures. Age and/or temperature effects can shift the total combined emissions from the RGB LED module.

Similarly, a selected shift in the total combined emissions from an RGB LED module is desirable in some applications. For example, if a white LED module is used in a photographic flash application, the desired spectral composition of light in a flash intended for daylight use is different from the desired spectral composition of light in a flash intended for use under tungsten-filament lighting, or for use under fluorescent lighting.

Color-tunable RGB LED modules have been developed that allow the user to control the LEDs to selectively vary the color content of the total combined emission. Basically, the user may selectively color tune the output of the RGB LED module to produce a “warm” white light (relatively richer in the red light) or a “cool” white light (relatively richer in the blue light). However, these color-tunable RGB LED modules have several contact pins, essentially a separate pin or pair of pins for each LED. The user sets the bias point of each LED separately by generating a control signal (typically a bias voltage) for each LED, and coupling the control signals through the contact pins. However, it is inconvenient and complicated for the user to generate and apply control signal for each LED independently. The proper control signals depend on the emission characteristics of each LED, and how the light outputs of the LEDs mix to form the desired total combined emission.

A color-tunable LED module providing a simpler control technique is desirable.

### BRIEF SUMMARY OF THE INVENTION

A two-terminal light-emitting diode (“LED”) device has a first terminal and a second terminal, and a first color LED and a second color LED. An intensity control device is coupled to the first color LED and a control circuit controls the intensity control device so as to produce a selected light intensity from the first color LED according to a control signal provided to the first terminal. The control signal also provides electrical power to the first color LED and to the second color LED.

### BRIEF DESCRIPTION OF THE DRAWINGS

FIG. 1 is a diagram of a two-terminal LED device according to an embodiment of the invention.

FIG. 2 is a diagram of a two-terminal RGB LED device using digital control according to another embodiment of the invention.

FIG. 3 is a diagram of a two-terminal RGB LED device using analog control according to another embodiment of the invention.

FIG. 4 is a diagram of a two-terminal RGB LED device using pulse-width modulation according to another embodiment of the invention.

FIG. 5 is a diagram of a two-terminal RGB LED device with an integrated sensor according to another embodiment of the invention.

FIG. 6 is a chromaticity diagram illustrating the modeled spectral output of an RGB LED device versus supply voltage according to an embodiment of the invention.

### DETAILED DESCRIPTION OF THE EMBODIMENTS

I. An Exemplary Color-Tunable Two-Terminal LED Device

FIG. 1 is a diagram of a two-terminal LED device 100 according to an embodiment of the invention. The two-terminal LED device 100 has a first color LED 102 and a second color LED 104. In other words, the first color LED 102 emits light of a first color (e.g. red) and the second color LED 104 emits light of second color (e.g. green). The light emitted by the first color LED 102 and the second color LED 104 is combined to form a total combined emission having an intermediate color (e.g. yellow).

The light output can also be controlled using the drive voltage supplied to an LED; however, the I-V characteristics of an LED mean that small changes in voltage cause large changes in current. Since light output is determined by current flowing through the LED, it is generally desirable that the drive voltage needs to be precise and stable. Drive current and on-time (time modulation) are two ways of reliably controlling light intensity from an LED. Pulse-width modulation is an example of a time modulation technique. Another example of a time modulation technique is bit angle modulation

The light intensity from the first color LED 102 is selectively controlled using an intensity control device 106, such as a pulse-width modulator (“PWM”), digital-to-analog controller (“DAC”), variable current sink or variable resistor in combination with a control signal (e.g. a variable supply voltage, Vₛᵤₚₚ). The control signal is coupled to a control circuit 108, which produces an intensity control signal to operate the intensity control device 106. For example, the control circuit is an analog, digital, or mixed circuit that sets the duty cycle of a PWM, the voltage level of a DAC, the current through a variable current source, or the resistance of a variable resistor according to the value of the control signal.

In some embodiments, the control signal is coupled directly to an intensity control device without an intervening control circuit, for example, when the intensity control device is a voltage-controlled variable resistor. This is particularly desirable for applications that do not need precise control over the relationship between Vₛᵤₚₚ and the color and intensity of the total combined emission.

The intensity control device 106 controls the intensity of light emitted by first color LED 102, which in turn controls the total combined emission of the two-terminal LED device 100. For example, if the intensity control device is variable resistor, less current will flow through the first color LED 102 as the resistance increases, diminishing its light intensity, and hence its contribution to the total combined emission from the LED device. The current through the second color LED 104, and its light intensity, remains constant. Continuing the example where the first color LED is a red LED and the second color LED is a green LED, the two-terminal LED device 100 emits yellow light when the variable resistor has low resistance, and emits greener light as the resistance is increased. If the first color LED is essentially shut off, the emission from the two-terminal LED is the color of the second color LED (e.g. green).

The control signal also provides the electrical power for the first color LED 102, the second color LED 104, and other components of the two-terminal LED device. Thus, the two-terminal LED device provides electrical power to the LEDs and color tuning of the LED device using only two terminals 110, 112. In a particular embodiment, the control signal is a supply voltage Vₛᵤₚₚ that is greater than the desired LED bias voltage. The control signal is applied to the first terminal 110, and the second terminal 112 is grounded. In alternative embodiments, the terminals are connected differently, for example, the second terminal is connected to a potential other than ground.

A DC-to-DC converter 114 converts the supply voltage Vₛᵤₚₚ to the LED voltage V_{LED}. The DC-to-DC converter is linear regulator, a switching regulator, or a charge pump-based regulator, for example. The DC-to-DC converter 114 allows Vₛᵤₚₚ to vary without changing V_{LED}. Thus, Vₛᵤₚₚ is used as a color control signal without changing the voltage provided to the first color LED 102 and the second color LED 104. This feature is not required in all embodiments, although it simplifies obtaining the desired total combined emission with the control signal. Otherwise, the intensity of light from the LEDs might vary as a function of the supply voltage. Another advantage in some applications is that the intensity control device and/or control circuit might optimally operate at a different voltage or over a different voltage range than the LEDs. Alternatively, the control signal includes a digital signal as well as a DC component (offset). The DC component provides power to the LEDs, while the digital signal provides desired intensity information to a digital control circuit, or directly controls one or more digital intensity control devices.

In an alternative embodiment, additional LEDs are included in a two-terminal LED device. These LEDs could be controlled or un-controlled. For example, the first color LED might be an orange-red LED and a third color LED might be a deep red LED controlled by the same intensity control signal from the control circuit. In another embodiment, a third color LED (e.g. a blue LED) is not controlled. Red, green, and blue light are combined to provide essentially white light from the two-terminal LED device. Tuning the first color LED allows selectively changing the color temperature of the white light.

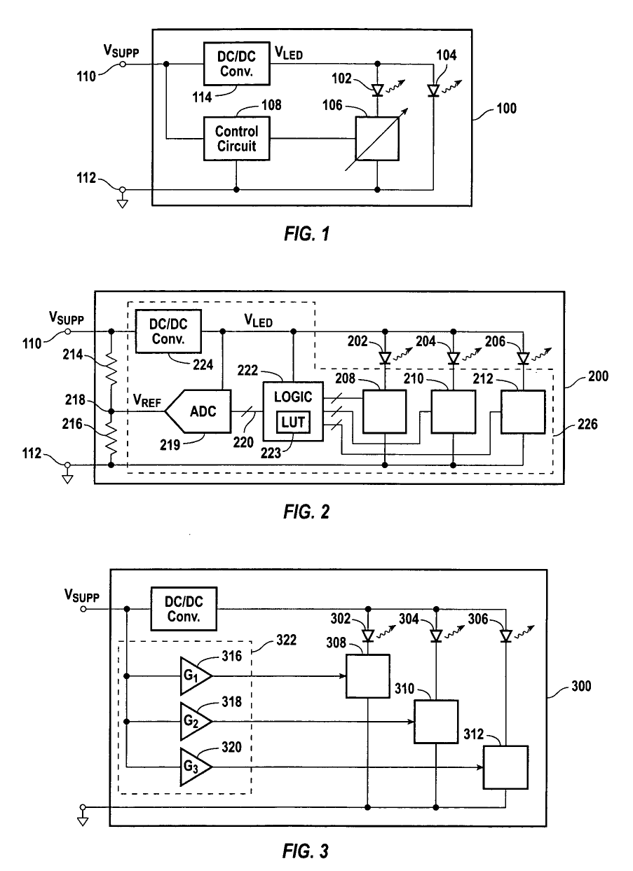

FIG. 2 is a diagram of a two-terminal RGB LED 200 device using digital control according to another embodiment of the invention. A control signal Vₛᵤₚₚ is provided to the first terminal 110, and the second terminal 112 is grounded. The control signal is converted to a voltage V_{LED} suitable for biasing the color LEDs 202, 204, 206. In a particular embodiment, the first color LED 202 is a red LED, the second color LED 204 is a green LED and the third color LED 206 is a blue LED. The intensity of each of the color LEDs is separately controlled by associated digital intensity control devices 208, 210, 212. Controlling each of the color LEDs in a two-terminal LED device is desirable because it allows tuning the color of the total combined emission as well as its intensity. Examples of suitable digital intensity control devices include current-output DACs and/or PWMs.

Generally, a current output DAC would be used as a digital intensity control device to vary the current flowing through the associated color LED. A PWM is basically a switch that is rapidly opened and closed to vary the duty cycle of the associated color LED. Increasing the duty cycle increases the light produced by the color LED. The PWM is typically switched at a rate much higher than the eye can detect. Using a PWM as a digital intensity control device is particularly desirable because light output versus duty factor is more linear than light output versus current. In an alternative embodiment, the digital intensity control device(s) is between the DC-to-DC controller and the color LED.

Resistors 214, 216 form a voltage divider that linearly converts Vₛᵤₚₚ into a reference voltage V_{ref} at node 218. An analog-to-digital converter (“ADC”) 219 uses V_{ref} to produce a digital reference signal 220. The digital reference signal 220 is provided to a digital control circuit (i.e. “logic”) 222 that drives the digital intensity control devices 208, 210, 212. In a particular embodiment, the digital control circuit 222 includes a look-up table (“LUT”) 223 or other digitally readable data and outputs the appropriate digital control signals to the digital intensity control devices 208, 210, 212 according to the control signal Vₛᵤₚₚ. The LUT is shown as being included in the digital control circuit 222, but could be external from the digital control circuit. The LUT is generated according to the total combined emission characteristics of the two-terminal LED device, which may be developed according to an individual device or generally for several individual devices. The techniques for converting an analog voltage control signal to produce a desired total combined emission is discussed in further detail in regard to FIG. 6.

The voltage divider is desirable to reduce the potential of the control signal to a potential more suitable for operating the ADC. In a particular example, Vₛᵤₚₚ ranges from about 5 V to about 12 V, which is undesirably high for some ADCs, but suitably above the voltage necessary to electrically power the color LEDs 202, 204, 206 after regulation by a DC-to-DC converter 224. The voltage divider drops V_{REF} to between about 1 and about 4 Volts. The minimum V_{LED} is governed by the maximum forward voltage required across any one LED in the LED array. This is typically about 4V for a green or blue LED. So, a V_{LED} of 5V will provide enough supply voltage to drive the DC-to-DC converter and drive the LEDs.

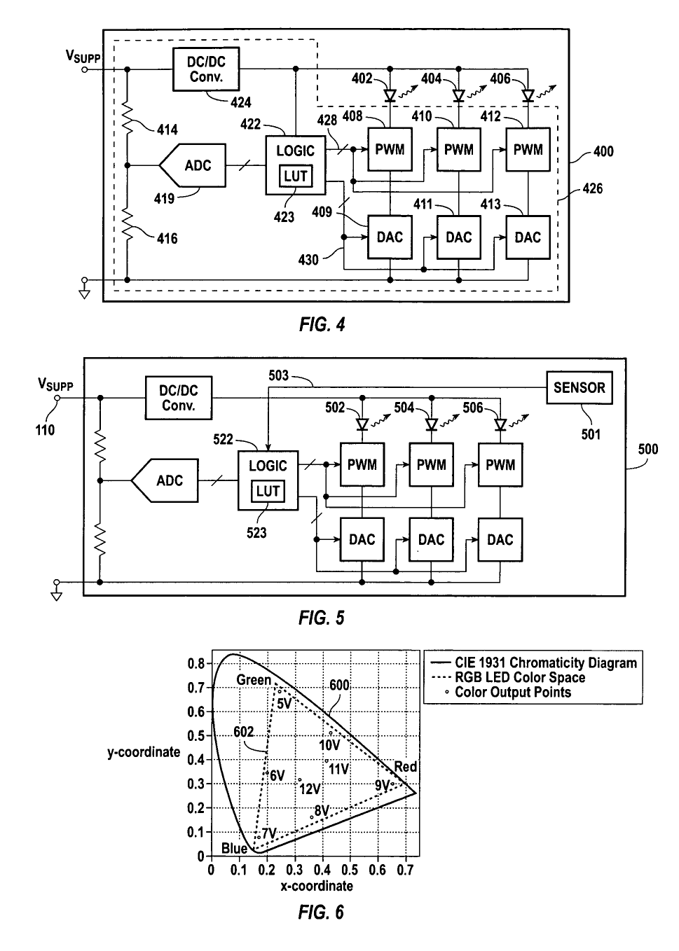

In a particular embodiment, the DC-to-DC converter 224, ADC 219, digital control circuit 222, and digital intensity control devices 208, 210, 212 are contained on an integrated circuit (“IC”) represented by dotted line 226. The resistors 214, 216 are optionally included in the IC (e.g., see FIG. 4). The digital circuitry is powered by V_{LED}, or alternatively by a second regulated voltage (not shown) from the DC-to-DC converter. The color LEDs 202, 204, 206 are typically separate chips mounted in a common package with the IC 226 using conventional die-attach and wire-bond techniques.

FIG. 3 is a diagram of a two-terminal RGB LED device 300 using an analog control circuit 322 according to another embodiment of the invention. Amplifiers 316, 318, 320 drive analog intensity control devices 308, 310, 312. Examples of analog intensity control devices include variable current sinks and voltage-controlled variable resistors. The amplifiers provide different amounts of gain. Unfortunately, light output is not linearly proportional to LED forward current; however, one could profile the LEDs to get a gamma correction curve to be used in an analog embodiment.

Linearity is not a problem when digital intensity control circuit is used in combination with an LUT because drive current does not have to be calculated on an assumption of linearity. Each LUT entry is determined through characterization of an LED device, and the intensity versus current relationship is mapped in the LUT.

FIG. 4 is a diagram of a two-terminal RGB LED device 400 using pulse-width modulation according to another embodiment of the invention. The two-terminal RGB device includes color LEDs 402, 404, 406, a DC-to-DC converter 424, an ADC 419, and resistors 414, 416 that operate similarly to those in FIG. 2. Each color LED has an associated PWM 408, 410, 412 and a current output DAC 409, 411, 413 in series with the PWMs. The current output DACs are alternatively between the color LEDs and the PWMs, or either or both of the current output DACs and PWMs are between the color LEDs and the DC-to-DC converter 424.

A digital control circuit (“logic”) 422 controls the PWMs 408, 410, 412 and the current output DACs 409, 411, 413. The digital control circuit 422 uses a digital reference signal from the ADC 419 in combination with an LUT 423 to generate digital intensity control signals that are sent to both the PWMs 408, 410, 412 and to the current output DACs 409, 411, 413 to individually control the intensity (brightness) of each color LED 402, 404, 406. The digital intensity control signal(s) sent to the PWMs are on a first bus 428, and the digital intensity control signal(s) sent to the current output DACs are on a second bus 430. Alternatively, the digital intensity control signals are sent on a common bus (not shown) to both the current output DACs and the PWMs.

Using a PWM in combination with a current output DAC is desirable because the DACs may be used to set the peak current through the associated color LED while the PWM is used to modulate the light intensity from the associated color LED. Time modulation is desirable because LED light output is linearly proportional to duty factor. Flicker will not occur if the PWM frequency is high enough (generally greater than 100 Hz). Hence, knowing the light intensity of the LED at one duty factor value allows one to calculate what the light intensities will be at different duty factor values. This is highly useful in creating an LUT. In a particular embodiment, a calibration process uses a camera that measures the color and intensity of an RGB module at a particular duty factor. Extrapolation calculations are performed to obtain the color and intensity at other duty factor values to complete the LUT mapping. Alternatively, each entry in an LUT mapping current to intensity is a measured value rather than a calculated value.

The DC-to-DC converter 424, ADC 419, resistors 414, 416, digital control circuit 426, current output DACs 409, 411, 413 and PWMs 408, 410,412 are fabricated on an IC 426. The IC 426 and color LEDs 402, 404, 406 are assembled as a hybrid circuit in a package using conventional techniques to provide the two-terminal LED device 400.

FIG. 5 is a diagram of a two-terminal RGB LED device 500 with an integrated sensor 501 according to another embodiment of the invention. In a particular embodiment the sensor 501 is an RGB sensor. Alternatively, the sensor is a different photo sensor or a temperature sensor. The sensor 501 detects the light emissions from the color LEDs 502, 504, 506 and provides a sensor signal or signals (e.g. a red sensor signal, a green sensor signal, and a blue sensor signal in the case of an RGB sensor) 503 to a digital control circuit (“logic”) 522. The digital control circuit 522 uses the sensor signal, in combination with a control signal Vₛᵤₚₚ provided to the terminal 110. In a particular embodiment, the sensor 501 is an RGB sensor and the sensor signal 503 is compared to a value in an LUT 523. If the sensor signal is not the expected value for the control signal, the digital control circuit 522 adjusts the intensity control signal(s) to one or more of the digital intensity control devices 508, 509, 510, 511, 512, 513 to achieve the proper (expected) sensor signal. Alternatively, the sensor is disposed to detect light from one or more of the color LEDs. For example, a sensor (not shown) is included in the two-terminal LED device of FIG. 1 to detect light emitted by the first color LED 102 and provides a sensor signal to the control circuit 108.

There is typically some variation in brightness (at a given bias level) between batches of color LEDs. This means that the combined emission of the two-terminal LED device can vary from part-to-part for the same control signal Vₛᵤₚₚ. There is typically less variation between sensors than between a combination of multiple color LEDs. Including an RGB sensor in the two-terminal LED device 500 reduces part-to-part variation at the user level. In other words, it provides more consistent and accurate light output at a selected control signal. This allows a user to provide a control signal according to accurately obtain a desired total combined emission.

An RGB sensor can also account for variations in light output arising from aging or thermal effects that affect the color LEDs. An LED is typically more susceptible to aging and temperature effects than a sensor. For example, if one or more of the color LEDs loses efficiency (i.e. brightness at a fixed bias or duty cycle) due to aging, the sensor signal(s) is used to boost the output. Similarly, if one or more color LEDs changes with temperature, the sensor provides a sensor signal that maintains the total combined emission at the desired color and/or brightness. Alternatively, the sensor 501 is a temperature sensor and the sensor signal indicates the temperature of the two-terminal LED device 500. The logic, in combination with the sensor signal and control signal, generates the intensity control signals to provide the desired total combined emission.

FIG. 6 is a chromaticity diagram 600 illustrating the modeled spectral output of an RGB LED device versus supply voltage according to the embodiment of FIG. 5. The triangle indicated by the dotted line 602 shows the RGB color space. Color output points for different control signals (i.e. different Vₛᵤₚₚ) are shown within the RGB color space 602 according to the Table 1:

TABLE 1

| | Output color | | |
|---|---|---|---|
| | (total combined | | |
| Vₛᵤₚₚ | emission) | x-coord | y-coord |
| 5 V | Green | 0.240 | 0.680 |
| 6 V | Cyan | 0.200 | 0.350 |
| 7 V | Blue | 0.170 | 0.080 |
| 8 V | Pink | 0.360 | 0.160 |
| 9 V | Red | 0.650 | 0.300 |
| 10 V | Yellow | 0.430 | 0.510 |
| 11 V | Warm White | 0.417 | 0.396 |
| 12 V | Cool White | 0.314 | 0.324 |

The example given in Table 1 was modeled using an 8-bit ADC, providing 255 control points, an 8-bit RGB sensor, providing 255 output values for each of the red, green, and blue sensors, and a 12-bit duty factor, providing 4095 different color LED duty cycles controlled by each of the red, green and blue PWMs. In other words, a duty factor of 0 means that the LED is turned off, and a duty factor of 4095 means that the LED is fully turned on. Many applications do not require this degree of set-ability or controllability. However, this example shows how the light output of a two-terminal RGB LED device can be tuned over the color space 602 by varying the supply voltage. The color output points 5V, 7V, 9V near the corners of the color space 602 provide the primary colors from essentially a single color LED. In other words, the green, blue, or red LED is turned on, and the other color LEDs are essentially turned off (very low duty cycle and/or current). Color output points 6V, 8V, 10V along the edges of the color space 602 provide mixed colors from essentially two of the color LEDs, namely: cyan, pink, and yellow. Color points 11V, 12V in the interior of the color space 602 provide essentially white light from all three color LEDs.

The color travel from green to blue to red to yellow to warm white to cool white in this example is arbitrary. The logic and/or LUT can be mapped to provide a different sequence of colors, or a non-sequential change of color. For example, a Vₛᵤₚₚ of 5 V might map to cool white, a Vₛᵤₚₚ of 6 V map to cyan, and a Vₛᵤₚₚ of 7 V map to red. Similarly, an 8-bit ADC allows many more (up to 255) possible color settings. The range of control signals and color travel is selected according to the application, as is the logic and mapping of the LUT to the total combined emission. In a particular embodiment, a two-terminal RGB LED device is used to produce white light and the control signal, LUT values, and logic is selected to tune the total combined emission of the two-terminal RGB LED device to produce white light having a selected color temperature.

Table 2 provides exemplary values for duty factors using PWMs and a 12-bit digital intensity control signal. The results are simulated, based on typical output characteristics of red, green, and blue LEDs:

TABLE 2

| | | PWM Duty | | | Output Color | | |
|---|---|---|---|---|---|---|---|
| | | Factor | | | (CIE XYZ Coord.) | | |
| Vₛᵤₚₚ | ADC code | Red | Green | Blue | X | Y | Z |
| 5 | 106 | 117 | 4095 | 23 | 7.80 | 22.05 | 2.58 |
| 6 | 127 | 176 | 4095 | 3289 | 13.42 | 23.55 | 30.21 |
| 7 | 148 | 113 | 323 | 4095 | 7.88 | 3.71 | 34.83 |
| 8 | 170 | 2495 | 348 | 4095 | 26.22 | 11.65 | 34.96 |
| 9 | 191 | 4095 | 264 | 249 | 32.28 | 14.91 | 2.47 |
| 10 | 212 | 2284 | 4095 | 112 | 24.58 | 29.18 | 3.44 |
| 11 | 233 | 3333 | 4095 | 1545 | 34.90 | 33.19 | 15.62 |
| 12 | 255 | 2150 | 4095 | 3675 | 29.18 | 30.16 | 33.57 |

Table 3 provides exemplary values output expected from an 8-bit RGB sensor. The results are simulated based on a typical RGB sensor:

TABLE 3

| | | Sensor | | | Output Color | | |
|---|---|---|---|---|---|---|---|
| | | Output | | | (CIE XYZ Coord.) | | |
| Vₛᵤₚₚ | ADC code | Red | Green | Blue | X | Y | Z |
| 5 | 106 | 19 | 214 | 60 | 7.80 | 22.05 | 2.58 |
| 6 | 127 | 29 | 240 | 182 | 13.42 | 23.55 | 30.21 |
| 7 | 148 | 15 | 50 | 157 | 7.88 | 3.71 | 34.83 |
| 8 | 170 | 101 | 66 | 165 | 26.22 | 11.65 | 34.96 |
| 9 | 191 | 149 | 42 | 26 | 32.28 | 14.91 | 2.47 |
| 10 | 212 | 98 | 229 | 71 | 24.58 | 29.18 | 3.44 |
| 11 | 233 | 139 | 247 | 127 | 34.90 | 33.19 | 15.62 |
| 12 | 255 | 101 | 255 | 202 | 29.18 | 30.16 | 33.57 |

Another way to look at Tables 2 and 3 is that they represent a portion of the contents of an LUT. For the case without an RGB sensor, the PWM output can be adjusted for each entry in Table 2 such that the LEDs output the target color for that entry's ADC code. For the case with an RGB sensor (Table 3), the LEDs are driven according to the logic to adjust the sensor output to the target value. In either case, the LUTs are developed using a module calibration process that is performed in the factory. In applications where precise mapping between Vₛᵤₚₚ and color output of an individual RGB LED module is not required, a generic LUT can be used (i.e. an LUT is established for an RGB LED design and used in each individual module). However, in that case part-to-part variation in the LEDs, drivers, detection circuitry, and RGB sensor can contribute to module-to-module color and/or intensity variation of the total combined emission for a given Vₛᵤₚₚ.

In a particular embodiment, the sensor outputs are used to tune the color of a two-terminal RGB LED device in cooperation with logic (see FIG. 5, ref. num. 522). The control signal Vₛᵤₚₚ indicates the desired output color. The logic compares the actual sensor outputs against the expected sensor outputs, and adjusts digital intensity control signals, which alternatively are analog intensity control signals, to tune the color output of the RGB LED device until the sensor outputs read the expected values. This allows the RGB LED device to maintain a more constant color output over the operating temperature range and/or as the LEDs age. For example, if the output of the blue LED drops off due to aging, this would be detected by the sensor and logic, and the duty cycle of the blue PWM could be increased to increase the intensity of the blue LED, thus tuning the total combined emission of the RGB LED device.

While the preferred embodiments of the present invention have been illustrated in detail, it should be apparent that modifications and adaptations to these embodiments might occur to one skilled in the art without departing from the scope of the present invention as set forth in the following claims.

What is claimed is:

1. A two-terminal light-emitting diode (“LED”) device comprising:
a first terminal;
a second terminal;
a first color LED;
a second color LED;
an intensity control device coupled to the first color LED; and
a control circuit controlling the intensity control device so as to produce a selected light intensity from the first color LED according to a control signal provided to the first terminal, the control signal providing electrical power to the first color LED and to the second color LED.

2. The two-terminal LED device of claim 1 wherein the control signal is a selected supply voltage and further comprising a DC-to-DC converter disposed between the first terminal and the first and second color LEDs.

3. The two-terminal LED device of claim 2 wherein the second terminal is coupled to ground potential.

4. The two-terminal LED device of claim 1 wherein the control circuit is a digital control circuit and the intensity control device is a digital intensity control device.

5. The two-terminal LED device of claim 4 further comprising a second digital intensity control device in series with the digital intensity control device.

6. The two-terminal LED device of claim 4 further comprising an analog-to-digital converter (“ADC”) disposed between the first terminal and the digital control circuit.

7. The two-terminal LED device of claim 6 further comprising a voltage divider disposed between the ADC and the first terminal.

8. The two-terminal LED device of claim 1 further comprising a second intensity control device coupled to the second color LED, wherein the control circuit also controls the second intensity control device so as to produce a second selected light intensity from the second color LED according to the control signal and a selected total combined emission from the two-terminal LED device.

9. The two-terminal LED device of claim 8 further comprising
a third color LED; and
a third intensity control device, wherein the control circuit also controls the third intensity control device so as to produce a third selected light intensity from the third color LED according to the control signal.

10. The two-terminal LED device of claim 9 wherein the selected total combined emission is white light having a selected color temperature.

11. The two-terminal LED device of claim 9 wherein the first color LED is a red LED, the second color LED is a green LED, and the third color LED is a blue LED.

12. The two terminal LED device of claim 1 further comprising a sensor providing a sensor signal to the control circuit.

13. The two-terminal LED device of claim 12 wherein the sensor is a temperature sensor.

14. The two-terminal LED device of claim 12 wherein the sensor is an optical sensor disposed to detect light from at least the first LED.

15. The two-terminal LED device of claim 9 further comprising a red-green-blue (“RGB”) sensor providing a sensor signal to the control circuit, the control circuit controlling the intensity control device, the second intensity control device, and the third intensity control device according to the control signal in combination with the sensor signal so as to produce a selected total combined emission.

16. The two-terminal LED device of claim 1 wherein the intensity control device is an analog intensity control device.

17. The two-terminal LED device of claim 4 further comprising a look-up table mapping a total combined emission of the two-terminal LED device to the control signal.

18. The two-terminal LED device of claim 17 wherein the look-up table is integrated with the digital control circuit.

19. The two-terminal LED device of claim 12 further comprising a look-up table mapping a total combined emission of the two-terminal LED device to the sensor signal.
